(19) United States
(12) Patent Application Publication
(10) Pub. No.: US 2019/0033933 A1
(43) Pub. Date: Jan. 31, 2019

(54) CACHE POLICY RESPONSIVE TO TEMPERATURE CHANGES

(71) Applicant: INTEL CORPORATION, Santa Clara, CA (US)

(72) Inventors: Ho Young Hur, Folsom, CA (US); Swaminathan Sathappan, Folsom, CA (US); Nisarg Pandya, Folsom, CA (US); Rohit S. Kenchanpura, Rancho Cordova, CA (US); Venkat Rohit Koppana, Rancho Cordova, CA (US); Santosh Bhat, Folsom, CA (US); Chandra Sekhar Anagani, El Dorado Hills, CA (US)

(21) Appl. No.: 15/834,008

(22) Filed: Dec. 6, 2017

(51) Int. Cl. G06F 1/20; G06F 1/28; G11C 7/04

(52) U.S. Cl. CPC G06F 1/206; G06F 3/0688; G11C 7/04; G06F 1/28

(57) ABSTRACT

Embodiments of the present disclosure are directed towards a computer system with cache policy that may be modified in response to temperature changes. In some embodiments, the system may include a memory storage having a first storage device with a first response time, and a second storage device with a second response time that may be higher than the first response time. The system may include a cache policy module to facilitate execution of I/O requests to access the memory storage. The cache policy module may be configured to restrict access to at least a portion of the first storage device and provide access to the second storage device, in response to an increase of temperature of the first storage device above a threshold. Other embodiments may be described and/or claimed.

### FIELD

Embodiments of the present disclosure generally relate to the field of storage devices and in particular to cache memory management.

### BACKGROUND

Current computer systems widely use storage systems, having “fast” storage devices and “slow” storage devices, where the fast storage device (e.g., fast storage device) may be smaller and/or faster than the slow storage device (e.g., slow storage device) and may be hidden from the user. The fast storage device may comprise a cache or a subset of the slow storage device). Current storage systems employ cache access policies that determine whether to write data through to the slow storage device or write back to the fast storage device. The fast storage device may store selected subsets of data blocks, e.g., from the logical block addressing (LBA) range on the slow storage device). By keeping copies of the LBAs considered important on the fast storage device, any input-output (I/O) request to access these data blocks can be handled faster than if the request were serviced by accessing just the slow storage device. However, such approach may put consistent stress to the fast storage device. For example, a thermal throttling limit may be reached. In other words, if the temperature in the cache memory rises above certain level, all input to and output from the fast storage device (cache) may be shut down and no more I/O transactions may occur. This may result in a catastrophic platform error, and the cache may lose some or all stored data.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example and not by way of limitation in the figures of the accompanying drawings.

FIG. 1 is a block diagram of an example computer system with cache policy that may be modified in response to temperature changes, in accordance with some embodiments.

FIG. 2 is a diagram illustrating an example interaction of components of the computer system of FIG. 1, in accordance with some embodiments.

FIG. 3 illustrates an example cache policy modification in response to temperature increase, in accordance with some embodiments.

FIG. 4 is a graph illustrating an example processing of write requests to the memory storage of the computer system of FIG. 1, in accordance with some embodiments.

FIG. 5 is an example process flow for processing a read request by the computer system of FIG. 1, in accordance with some embodiments.

FIG. 6 is an example process flow for processing a write request by the computer system of FIG. 1, in accordance with some embodiments.

FIG. 7 is a flow diagram illustrating an example process of operation of a computer system with cache policy that may be modified in response to temperature changes, in accordance with some embodiments.

FIG. 8 illustrates an example computing system suitable for use with the embodiments of FIGS. 1-7, in accordance with some embodiments.

### DETAILED DESCRIPTION

Embodiments of the present disclosure include techniques and configurations for a computer system with cache policy that may be modified in response to temperature changes. In some embodiments, the computer system may include a storage having a first storage device with a first response time, and a second storage device coupled with the first storage device. The second storage device may have a second response time that may be higher than the first response time. The system may further include a cache policy module to facilitate execution of I/O requests to access the memory storage of the computer system. The cache policy module may be configured to restrict access to at least a portion of the first storage device and provide access to the second storage device, in response to an increase of temperature of the first storage device above a threshold. In some embodiments, the first memory device may comprise a cache memory of the computer system, and the second memory device may comprise a main memory of the computer system.

In the following description, various aspects of the illustrative implementations will be described using terms commonly employed by those skilled in the art to convey the substance of their work to others skilled in the art. However, it will be apparent to those skilled in the art that embodiments of the present disclosure may be practiced with only some of the described aspects. For purposes of explanation, specific numbers, materials and configurations are set forth in order to provide a thorough understanding of the illustrative implementations. However, it will be apparent to one skilled in the art that embodiments of the present disclosure may be practiced without the specific details. In other instances, well-known features are omitted or simplified in order not to obscure the illustrative implementations.

In the following detailed description, reference is made to the accompanying drawings that form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), (A) or (B), or (A and B). For the purposes of the present disclosure, the phrase “A, B, and/or C” means (A), (B), (C), (A and B), (A and C), (B and C), or (A, B and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

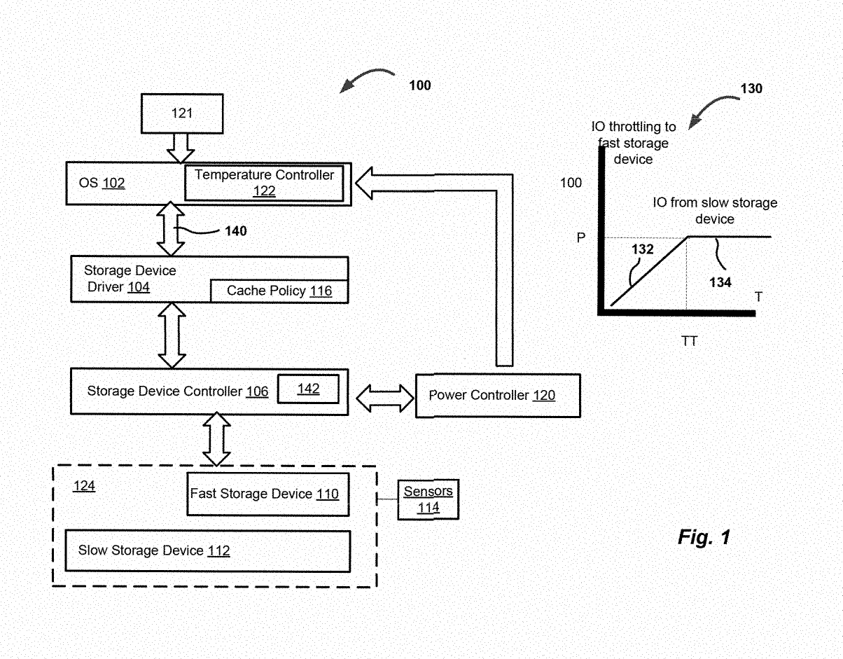

FIG. 1 is a block diagram of an example computer system with cache policy that may be modified in response to temperature changes, in accordance with some embodiments. In embodiments described herein, the computer system 100 may be configured to facilitate I/O requests to access storage 124 of the computer system 100 so as to prevent or limit errors associated with the fast storage device overheating, by restricting access to at least some portions of the fast storage device and providing access to the slow storage device of the computer system.

The computer system 100 may include an operating system (OS) 102 that may be executed on a processor 121 of the computer system 100. The OS 102 may include any known and commercially available operating system. In embodiments, the OS 102 may run a storage device driver 104, to control and operate a memory of the computer system 100 (e.g., storage 124), and facilitate communication of the memory with the remainder of the computer system 100. The storage device driver 104 may be communicatively coupled with a storage device controller 106, to manage the storage devices and present them to the computer system as logical units. In embodiments, the storage device driver 104 may be implemented as software executable on the processor 121 of the computer system 100.

The storage device controller 106 may be operated by the storage device driver 104, to facilitate I/O requests to access (e.g., read to or write from) the storage 124 of the computer system 100. In embodiments, the driver 104 may inform the controller 106 whether an I/O request may be serviced by the slow storage device and/or the fast storage device based on the cache policy, in accordance with the embodiments described herein. The controller 106 may process the I/O requests accordingly. In embodiments, the controller 106 may include a temperature register 142, to store device temperature readings (as described below in greater detail).

The storage 124 of the computer system 100 may include a first storage device 110 and second storage device 112. In embodiments, the first storage device 110 may have a response time, and a second storage device 112 may have a response time that may be higher than the first response time. In other words, the first storage device 110 may perform faster than the second storage device 112.

In embodiments, the first storage device 110 may comprise a cache storage for the second storage device 112 of the computer system 100. For example, the first storage device 110 (hereinafter fast storage device) may comprise a solid state drive (SSD). The second storage device 112 (hereinafter slow storage device) may comprise a hard disk drive (HDD) or a slow SSD.

In one embodiment, reference to non-volatile memory may refer to non-volatile memory (NVM) devices whose state is determinate even if power is interrupted to the device. In one embodiment, the NVM device can comprise a block addressable mode memory device, such as NAND or NOR technologies, or more specifically, multi-threshold level NAND flash memory, NOR flash memory, and the like. A NVM device can also include a byte-addressable write-in-place three dimensional crosspoint memory device, or other byte addressable write-in-place NVM devices, such as single or multi-level Phase Change Memory (PCM) or phase change memory with a switch (PCMS), NVM devices that use chalcogenide phase change material (for example, chalcogenide glass), resistive memory including metal oxide base, oxygen vacancy base and Conductive Bridge Random Access Memory (CB-RAM), nanowire memory, ferroelectric transistor random access memory (FeTRAM), magneto resistive random access memory (MRAM) that incorporates memristor technology, spin transfer torque (STT)-MRAM, a spintronic magnetic junction memory based device, a magnetic tunneling junction (MTJ) based device, a DW (Domain Wall) and SOT (Spin Orbit Transfer) based device, a thyristor based memory device, or a combination of any of the above, or other memory.

In embodiments, the “slow” storage device 112 may be implemented as a Serial Advanced Technology Attachment (SATA) hard disk drive (HDD), SATA solid state drive (SSD), Non-Volatile Memory express (NVMe) SSD, Embedded Multimedia Card (eMMC), or Universal Flash Storage (UFS) or any other possible implementations of an I/O interface between the storage device and the computing system 100. In embodiments, the “fast” storage device 110 may also be any storage device that may have faster (lower) response times than the slow storage device 112.

In embodiments, the fast storage device 110 may have one or more temperature sensors 114 disposed at the storage device. For example, the sensors 114 may be embedded with the fast storage device 110. For example, multiple sensors 114 may be disposed at different locations on the device and may be subject to different amounts of airflow. The sensors 114 may be configured to provide readings of the temperature of the fast storage device 110. For example, the OS 102 may determine the temperature of the storage devices by sending a polling command over the I/O bus 140, using the storage device standard protocol, such as, for example, Serial Attached SCSI (SAS), SATA, PCIe, or NVMe.

In embodiments, the system 100 may employ the storage caching solution to identify the stored data that has the greatest impact on user experience, ensuring that access to that data may be as fast as possible. The storage device driver 104 may implement caching algorithm to understand what stored data has the biggest impact on user experience. Caching algorithm may utilize cache policy, which may determine whether to write through to the slow storage device 112 or write back to the fast storage device 110. Accordingly, the fast storage device 110 may work as cache and may stores selected subsets of data blocks from the LBA range on the slow storage device 112.

In embodiments, to provide the above-described caching solution, the storage device driver 104 may include a cache policy module 116. In some embodiments, the cache policy module 116 may be implemented as software executable (e.g., as part of the storage device driver 104's decision making engine). In some embodiments, the cache policy module 116 may be implemented as firmware, e.g., in computer systems with lower level operating systems.

In embodiments described herein, the cache policy module 116 may be configured to control execution of I/O requests to access the storage 124 of the computer system 100. For example, the cache policy module 116 may restrict access to a portion (or all) of the fast storage device 110 and provide access to the slow storage device 112, in response to an increase of temperature of the fast storage device 110 above a temperature threshold. In embodiments, there may be several temperature thresholds associated with the fast storage device 110, and correspondingly, several modification of the cache policy related to facilitation of the I/O access requests. For example, the cache policy module 116 may throttle (restrict) access to different portions (different volumes) of the cache memory (fast storage device), depending on a temperature threshold reached at the fast storage device 110 and sensed by the sensors 114.

The graph 130 illustrates an example implementation of the cache policy that may modify handling of I/O access requests to the storage 124. As shown, the I/O access requests to the fast storage device 110 may be increasingly throttled (e.g., reduced, as shown in portion 132 of the graph 130) until the temperature T associated with the fact disk reaches a temperature threshold TT. After the temperature reaches the temperature threshold TT, the cache policy module 116 may cause some of the I/O access requests to be handed over from the fast storage device 110 to the slow storage device 112, while some percentage P of the I/O access requests may be throttled (e.g., reduced or restricted) at the fast storage device 110, as shown in portion 134 of the graph 130. At a particular threshold TT. In some instances, e.g., when TT reaches 80 degrees Celsius, all I/O access requests may be throttled (restricted or denied) at the fast storage device 110, e.g., P equals 100%.

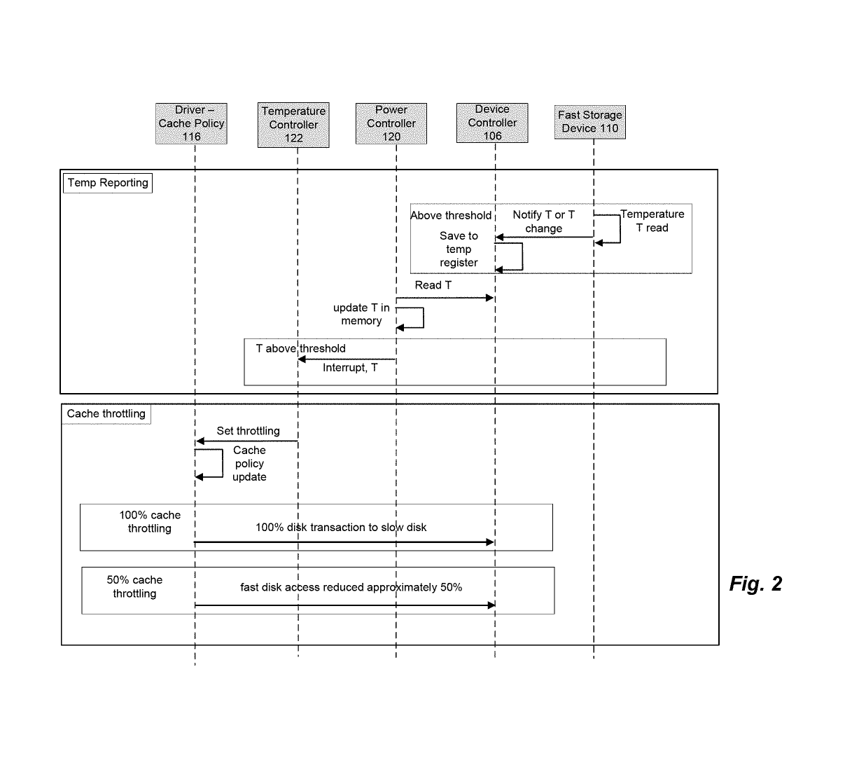

In embodiments, the computer system 100 may further include a power controller 120 configured to provide power to the storage 124 and disk controller 106. In embodiments, the OS 102 of the computer system may include a temperature controller 122 configured to collect temperature information associated with the computer system 100, including temperature readings associated with the fast storage device 110. The collection of temperature readings is described in greater detail in reference to FIG. 2.

FIG. 2 is a diagram illustrating an example interaction of components of the computer system of FIG. 1, in accordance with some embodiments. For ease of understanding, like components of FIGS. 1 and 2 are indicated by like numerals.

As shown, at the fast storage device 110 the temperature T may be read continuously or periodically, e.g., by sensors 114. The temperature T readings (or change in T above a threshold) may be provided by the sensors to the storage device controller 106. At storage device controller 106, the temperature (or its changes above the threshold) may be continuously or periodically saved in the temperature register 142 (FIG. 1).

The power controller 120 may continuously or periodically read temperature T data stored at the storage device controller 106 and make corresponding updates in its memory. When the temperature T reaches or exceeds the threshold TT, the power controller 120 may generate an interrupt signal and provide the T readings to the temperature controller 122. The temperature controller 122 may set a throttling value (e.g., percentage of I/O access requests that may not be processed at the fast storage device 110 level, or a portion of the fast storage device 110 memory, access to which may be restricted for the I/O access requests) and provide the throttling value to the cache policy module 116. The cache policy module 116 may update the cache policy accordingly and cause the updated policy to be implemented on the storage 124. In other words, as shown, if the throttling is set to 50%, the access to the fast storage device 110 may be reduced to approximately 50%, and the access may be continued to be provided to the slow storage device 112.

If throttling is set to 100%, the access to the fast storage device 110 may be reduced to approximately 0%, e.g., access to 100% of the fast storage device 110 memory may be denied and all I/O access requests may be serviced at the slow storage device 112. In embodiments, the cache policy module 116 may cause the data blocks stored in the portion of the fast storage device 110 memory, to which access is to be denied, to be marked as discarded data blocks.

The component interaction diagram is provided for the purposes of illustration. Different arrangements with regard to cache policy changes in response to fast storage device 110 temperature change may be possible. For example, the temperature readings may be provided to the cache policy module 116, and the cache policy module 116 may have a logic configured to select a throttling value that corresponds to a particular temperature threshold. In other words, the decision making logic may reside in the cache policy module 116. The sensors 114 may provide the temperature readings to the storage device driver 104 and the cache policy module 116 within the driver may make decisions with regard to updating the cache policy (e.g., setting throttling values) based on the provided temperature data.

Generally, some or all of the functions described with respect to the temperature controller and power controller may be distributed in a different way, for example, these functions may be performed by the logic associated with the cache policy module 116.

In some embodiments, the cache policy may have multiple temperature thresholds associated with the fast storage device 110, and multiple corresponding throttling values. For example, there may be a first temperature threshold TT1 (e.g., 60 degrees Celsius) and a corresponding throttling value of 50% (e.g., access to 50% of the fast storage device 110 memory may be restricted or denied). Further, there may be a second temperature threshold TT2 (e.g., 70 degrees Celsius) and a corresponding throttling value of 70% (e.g., access to 70% of the fast storage device 110 may be restricted or denied). Yet further, there may be a third temperature threshold TT3 (e.g., 80 degrees Celsius) and a corresponding throttling value of 100% (e.g., access to 100% of the fast storage device 110 may be restricted or denied). It is understood that the temperature thresholds are provided herein for purposes of explanation and are not limiting this disclosure. In general, any temperature values may be used as temperature thresholds, depending on technological requirements and implementation details.

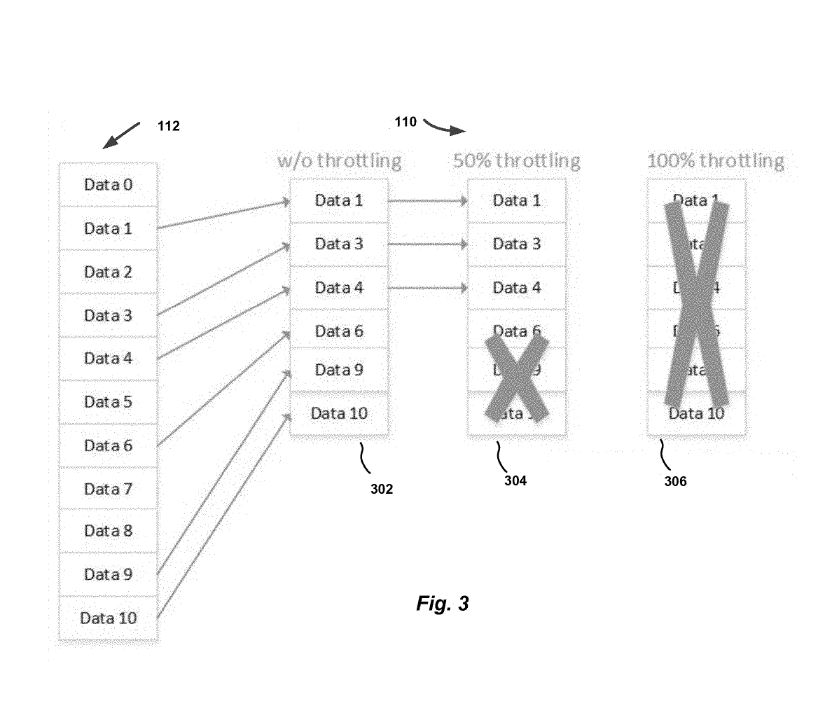

FIG. 3 illustrates an example cache policy memory modification in response to temperature increase, in accordance with some embodiments. For example, eleven data blocks Data 0 to Data 10 may be stored the slow storage device 112, out of which data blocks Data 1, Data 3, Data 4, Data 6, Data 9, and Data 10 may also be stored on the fast storage device 110 without throttling (access restriction), as shown on view 302. If throttling is selected to be 50%, access to the half of the data blocks (e.g., Data 6, Data 9, and Data 10) stored on the fast storage device 110 may be restricted (denied, view 304), and these data blocks may be marked as discarded. If throttling is selected to be 100%, access to all data blocks (e.g., Data 1, Data 3, Data 4, Data 6, Data 9, and Data 10) stored on the fast storage device 110 may be restricted (denied, view 306), and these data blocks may be marked as discarded. The processing of the I/O requests may be transferred to the slow storage device 112.

In embodiments, when the temperature of the fast storage device 110 returns to the values below the threshold, the cache policy module 116, in response to a decrease of the temperature to a value below the threshold, may direct to resume access to the fast storage device 110, e.g., to the cached data blocks (LBA) from the slow storage device 112 that are cached in the fast storage device 110.

As briefly described above, the I/O access request may include read requests (e.g., requests to read data from the storage 124 of the system 100), and write requests (e.g., requests to write data to the storage 124 of the system 100).

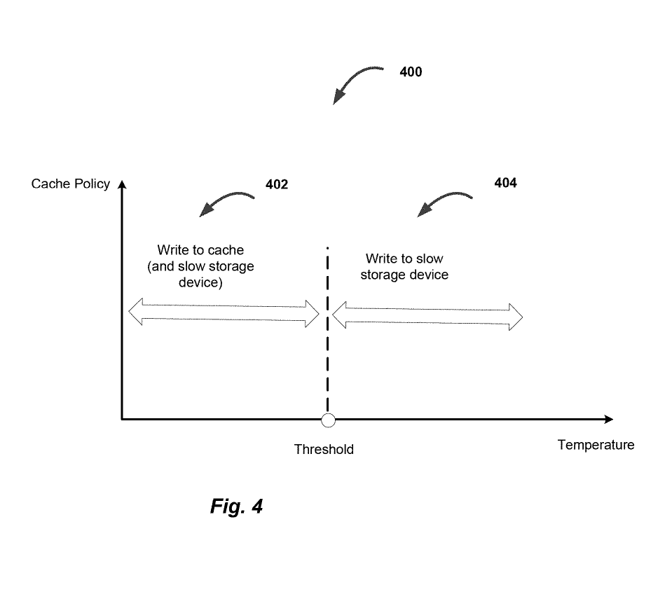

FIG. 4 is a graph illustrating an example processing of write requests to the memory storage of the computer system of FIG. 1, in accordance with some embodiments. As shown, the cache policy (operated by the cache policy module 116) may provide for access to the fast storage device 110 (e.g., cache memory of the slow storage device 112)) and slow storage device 112 of the system 100, in response to a write request (portion 402 of the graph 400). When the temperature of the fast storage device 110 reaches a threshold, access to the cache (110) may be denied and all write requests will be serviced at the slow memory device 112 (portion 404 of the graph 400). In other words, the data to be written to the storage 124 of the system 100 may be written only to the slow storage device 112 of the system 100.

Read requests may be processed in a somewhat similar manner to that described in reference to FIG. 4. The processing of the read and write requests by the computer system of FIG. 1 are described below in a greater detail.

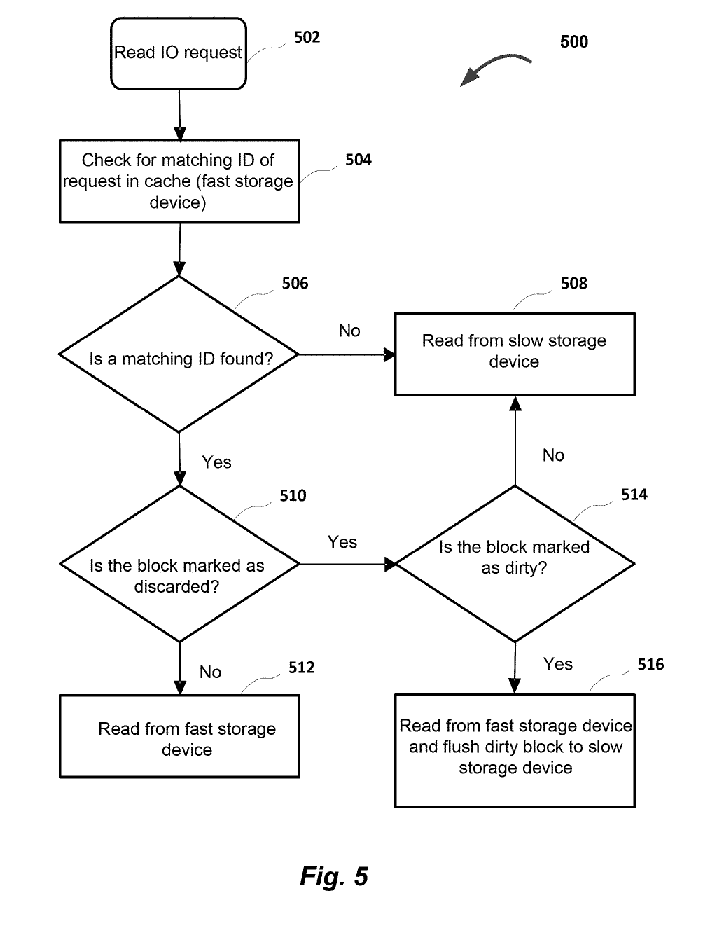

FIG. 5 is an example process flow for processing a read request by the computer system of FIG. 1, in accordance with some embodiments. The process 500 may be performed by some components of the system 100 of FIG. 1, including the cache policy module 116.

The process 500 may begin at block 502 and include receiving an I/O access request, e.g., a read request.

At block 504, the process 500 may include determining whether the read request may be processed at the cache storage (e.g., fast storage device 110). For example, every I/O access request may have an associated unique identifier (e.g., address) to locate the data in a disk. Since the cache storage may store copies of a small set of data available in the slow storage device, the storage device driver 104 (e.g., cache policy module 116) may keep track of the unique identifier of each data block that is stored in the cache, in a lookup table. The cache driver may use this lookup table to identify whether a I/O access request may be serviced by the cache storage (fast storage device 110). Accordingly, the lookup table may be checked to see if a matching unique identifier is stored in the table, to check whether the I/O access request may be serviced by the cache.

At decision block 506 the process 500 may determine whether the cache storage may service the I/O access request, e.g., whether a unique identifier associated with the request may be found in lookup table. If no matching ID is found, the process 500 may move to block 508, where the read request may be processed by the slow storage device 112.

If the matching ID is found, at decision block 510 the process 500 may check whether there are data blocks in the cache storage (fast storage device 110) that may be marked as discarded. As discussed in reference to FIGS. 2-3, data blocks in the restricted area of the cache storage may be marked as discarded. For example, a tag indicating a discarded block may be a single bit that may be associated with each entry in the lookup table. The cache policy module may use this bit to mark some data blocks as discarded. For example, setting this bit to ‘1’ may mean that the data block may be discarded.

If no discarded data blocks in the cache storage are identified (which means there are no restrictions to access the cache memory), at block 512 the process 500 may provide for reading the requested data from the fast storage device 110 (cache memory).

If a discarded data block in the cache storage is identified, the process 500 may move to a decision block 514. At decision block 514 it may be determined whether the discarded data block is marked as a dirty data block. The dirty block indication may mean that the data associated with this data block (e.g., LBA) in the cache storage (fast storage device 110) was recently updated, while its copy in the slow storage device 112 may not have been yet updated, in other words, the copy of the data block in the slow storage device is “older” than the copy of the data block in the fast storage device 110.

If the data block is clean, e.g., the data in the cache storage (fast storage device 110) and the slow storage device 112 are same, at block 514 the read of data from the slow storage device 112 may occur.

If the discarded data block is indicated as a dirty block, at block 516 the read of data from the fast storage device 110 may occur and the dirty data may be flushed (updated) to the slow storage device 112.

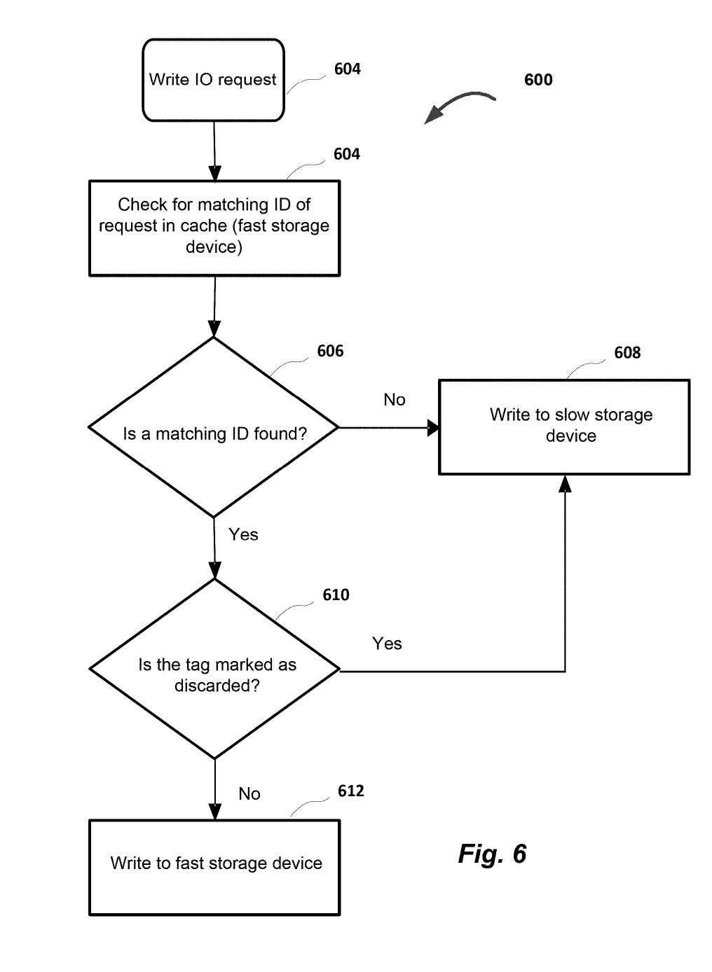

FIG. 6 is an example process flow for processing a write request by the computer system of FIG. 1, in accordance with some embodiments. The process 600 may be performed by some components of the system 100 of FIG. 1, including the cache policy module 116.

The process 600 may begin at block 602 and include receiving an I/O access request, e.g., a write request.

At block 604, the process 600 may check the lookup table to see whether a unique identifier associated with the write request is present in the cache memory, similar to the process described in reference to block 504 of FIG. 5.

At decision block 606, may include determining whether the write request may be processed at the cache storage. If no matching ID is found, the process 600 may move to block 608, where the write request may be processed by the slow storage device 112. If the matching ID is not found, the process 600 may move to block 608, where the write request may be processed by the slow storage device (in other words, the data associated with the write request may be written to the slow storage device).

If the matching ID is found, the process 600 may move to a decision block 610. At decision block 610 the process 600 may check whether there are data blocks in the cache storage(fast storage device 110) that may be marked as discarded. If the discarded data blocks are identified, the process 600 may move to block 608. If the discarded data blocks are not found, the process 600 may move to block 612, where the write request may processed by the fast storage device 110 (cache memory), e.g., the data may be written to the fast storage device 110.

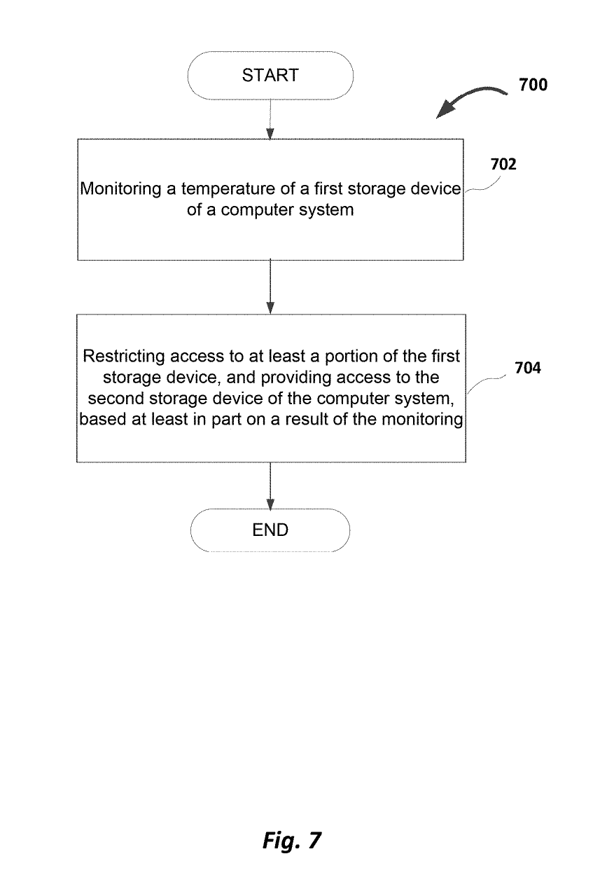

FIG. 7 is a flow diagram illustrating an example process of operation of a computer system with cache policy that may be modified in response to temperature changes, in accordance with some embodiments. The process 700 may comport with embodiments described in reference to FIGS. 1-6. In embodiments, the process 700 may be performed by the cache policy module 116 of FIG. 1.

The process 700 may begin at block 702 and include monitoring, by the cache policy module of the computer system, a temperature of a first storage device of the computer system. In embodiments, monitoring the temperature of the first storage device may include determining that the temperature of the first storage device exceeds a threshold.

The storage of the computer system may include the first storage device and a second storage device, wherein a response time of the first storage device may be lower than a response time of the second storage device.

At block 704, the process 700 may include restricting, by the cache policy module, access to at least a portion of the first storage device, and providing access to the second storage device, based at least in part on a result of the monitoring. For example, restricting access to the first storage device may include denying access to a portion of the memory of the first storage device, or denying access to all memory of the first storage device, when the temperature of the first storage device exceeds a threshold.

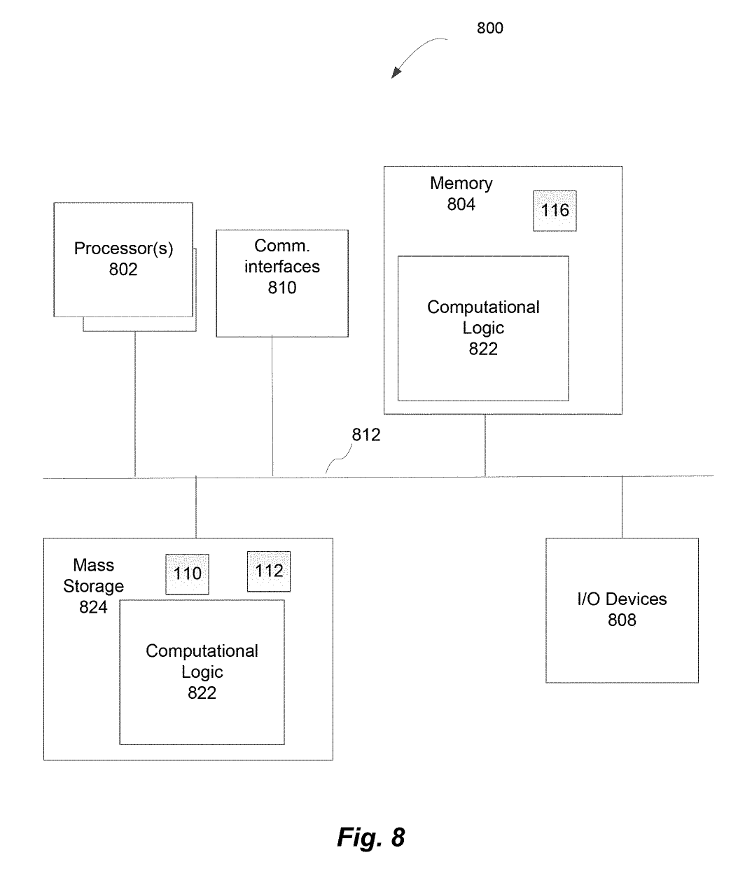

FIG. 8 illustrates an example computing system suitable for use with the embodiments of FIGS. 1-7, in accordance with some embodiments. In some embodiments, example computing system 800 may include various components described in reference to FIG. 1, such as, for example, the fast and slow storage devices 110 and 112 (with associated temperature sensors 114) and the cache policy module 116.

As shown, computing system 800 may include one or more processors or processor cores 802 and system memory 804. For the purpose of this application, including the claims, the terms “processor” and “processor cores” may be considered synonymous, unless the context clearly requires otherwise. The processor 802 may include any type of processors, such as a central processing unit (CPU), a microprocessor, and the like. The processor 802 may be implemented as an integrated circuit having multi-cores, e.g., a multi-core microprocessor.

The computing system 800 may include mass storage devices 824, such as solid state drives, volatile memory (e.g., dynamic random-access memory (DRAM), and so forth)). In general, system memory 804 and/or mass storage devices 824 may be temporal and/or persistent storage of any type, including, but not limited to, volatile and non-volatile memory, optical, magnetic, and/or solid state mass storage, and so forth.

Volatile memory may include, but is not limited to, static and/or dynamic random-access memory. Non-volatile memory may include, but is not limited to, electrically erasable programmable read-only memory, phase change memory, resistive memory, and so forth. In embodiments, the mass storage devices 824 may include the fast storage device 110 and slow storage device 112 as described in reference to FIG. 1.

The computing system 800 may further include input/output (I/O) devices 808 (such as display, soft keyboard, touch sensitive screen, image capture device, and so forth) and communication interfaces 810 (such as network interface cards, modems, infrared receivers, radio receivers (e.g., Near Field Communication (NFC), Bluetooth, WiFi, 4G/5G Long Term Evolution (LTE), and so forth).

The communication interfaces 810 may include communication chips (not shown) that may be configured to operate the device 800 in accordance with a Global System for Mobile Communication (GSM), General Packet Radio Service (GPRS), Universal Mobile Telecommunications System (UMTS), High Speed Packet Access (HSPA), Evolved HSPA (E-HSPA), or Long-Term Evolution (LTE) network. The communication chips may also be configured to operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chips may be configured to operate in accordance with Code Division Multiple Access (CDMA), Time Division Multiple Access (TDMA), Digital Enhanced Cordless Telecommunications (DECT), Evolution-Data Optimized (EV-DO), derivatives thereof, as well as any other wireless protocols that are designated as 3G, 4G, 5G, and beyond. The communication interfaces 810 may operate in accordance with other wireless protocols in other embodiments.

The above-described computing system 800 elements may be coupled to each other via system bus 812, which may represent one or more buses. In the case of multiple buses, they may be bridged by one or more bus bridges (not shown). Each of these elements may perform its conventional functions known in the art. In particular, system memory 804 and mass storage devices 824 may be employed to store a working copy and a permanent copy of the programming instructions implementing firmware, an operating system and/or one or more applications to be executed on computing system. For example, system memory 804 may include instructions comprising the cache policy module 116.

Computational logic 822 may be implemented in assembler instructions supported by processor(s) 802 or high-level languages that may be compiled into such instructions.

The number, capability, and/or capacity of the elements 802, 810, 812 may vary, depending on whether computing system 800 is used as a mobile computing system, such as a tablet computing system, laptop computer, game console, or smartphone, or a stationary computing system, such as a set-top box or desktop computer. Their constitutions are otherwise known, and accordingly will not be further described.

At least one of processors 802 may be packaged together with memory having computational logic 822 to form a System in Package (SiP) or a System on Chip (SoC). In various implementations, the computing system 800 may comprise a mobile computing system, such as a smartphone, a tablet, a personal digital assistant (PDA), an ultra mobile PC, or any other mobile computing system. In various embodiments, the computing system may comprise a laptop, a netbook, a notebook, or an ultrabook. In further implementations, the computing system 800 may be any other electronic device that processes data.

According to various embodiments, the present disclosure describes a number of examples.

Example 1 may be a computer system, comprising: a first storage device having a first response time, and a second storage device coupled with the first storage device, and having a second response time that is higher than the first response time; and a cache policy module to facilitate execution of input-output (I/O) requests to access the memory storage of the computer system, wherein the cache policy module is to restrict access to at least a portion of the first storage device and provide access to the second storage device, in response to an increase of temperature of the first storage device above a threshold.

Example 2 may include the computer system of example 1, wherein the first storage device comprises a cache of the second storage device.

Example 3 may include the computer system of example 2, wherein the second memory device comprises at least one of: a Serial Advanced Technology Attachment (SATA) hard disk drive (HDD), SATA solid state drive (SSD), Non-Volatile Memory express (NVMe) SSD, Embedded Multimedia Card (eMMC), or Universal Flash Storage (UFS).

Example 4 may include the computer system of example 2, wherein the first storage device comprises a solid state drive (SSD or a hard disk drive (HDD).

Example 5 may include the computer system of example 1, further comprising one or more thermal sensors coupled with the first storage device, to provide readings of the temperature of the first storage device to the cache policy module.

Example 6 may include the computer system of example 1, wherein the cache policy module, in response to a decrease of the temperature of the first storage device to a value below the threshold, is to resume access to the first storage device.

Example 7 may include the computer system of example 1, further comprising a storage device controller coupled with the processor, wherein the storage device controller is to service the I/O requests according to instructions provided by the cache policy module.

Example 8 may include the computer system of example 7, wherein the cache policy module to restrict access to at least a portion of the first storage device includes to cause the storage device controller to deny access to the portion of the first storage device, and to cause data blocks stored in the portion of the first storage device to be marked as discarded data blocks.

Example 9 may include the computer system of example 8, wherein the I/O requests include a write request, wherein the cache policy module to control execution of input-output (I/O) requests includes to, in response to the write request, cause the storage device controller to: determine that the write request is to be serviced by the first storage device; determine that at least some of data blocks stored in the first storage device are marked as the discarded data blocks; and write data associated with the write request to the second storage device.

Example 10 may include the computer system of example 8, wherein the I/O requests include a read request, wherein the cache policy module to control execution of input-output (I/O) requests includes to, in response to the read request, cause the storage device controller to: determine that the read request is to be serviced by the first storage device; determine that at least some of data blocks stored in the first storage device are marked as the discarded data blocks; determine that at least one of the discarded data blocks is marked as a dirty block; read data associated with the read request from the first storage device; and update the data block marked as the dirty block on the second storage device, wherein a dirty block mark indicates that a data block has been updated on the first storage device, with respect to a copy of the data block stored on the second storage device.

Example 11 may include the computer system of example 1, wherein the cache policy module comprises one of software module executable on a processor of a computer system, or firmware.

Example 12 may include the computer system of any examples 1 to 11, wherein the threshold is about 80 degrees Celsius, wherein the cache policy module to restrict access to at least a portion of the first storage device includes to deny access to the first storage device.

Example 13 may be one or more non-transitory computer-readable media having instructions to control execution of input-output (I/O) requests to access a memory of a computer system, wherein the memory comprises first and second storage devices, wherein a response time of the first storage device is lower than a response time of the second memory device, wherein the instructions, in response to execution on a processor of the computer system, cause the processor to: determine that a temperature of the first storage device is above a threshold; and restrict access to at least a portion of the first storage device, and provide access to the second storage device.

Example 14 may include the non-transitory computer-readable media of example 13, wherein the instructions further cause the processor to deny access to the portion of the first storage device, and to mark as discarded data blocks stored in the portion of the first memory device.

Example 15 may include the non-transitory computer-readable media of example 13, wherein the I/O requests include a write request, wherein the instructions further cause the processor to: determine that the write request is to be serviced by the first storage device; determine that at least some of data blocks stored in the first storage device are marked as the discarded data blocks; and write data associated with the write request to the second memory device.

Example 16 may include the non-transitory computer-readable media of example 13, wherein the I/O requests include a read request, wherein the instructions further cause the processor to: determine that the read request is to be serviced by the first storage device; determine that at least some of data blocks stored in the first storage device are marked as the discarded data blocks; determine that at least one of the discarded data blocks is marked as a dirty block; read data associated with the read request from the first storage device; and update the data block marked as the dirty block on the second storage device, wherein a dirty block mark indicates that a data block has been updated on the first storage device, with respect to a copy of the data block stored on the second storage device.

Example 17 may include the computer system of any examples 13 to 16, wherein the first storage device comprises a cache of the second storage device.

Example 18 may be a method, comprising: monitoring, by a cache policy module of a computer system, a temperature of a first storage device, wherein a memory storage of the computer system comprises the first storage device and a second storage device, wherein a response time of the first storage device is lower than a response time of the second memory device; and restricting, by the cache policy module, access to at least a portion of the first storage device, and providing access to the second storage device, based at least in part on a result of the monitoring.

Example 19 may include the method of example 18, wherein monitoring the temperature of the first storage device includes determining, by the cache policy module, that the temperature of the first storage device exceeds a threshold.

Example 20 may include the method of example 18, further comprising: updating, by the cache policy module, a cache policy of the computer system, based at least in part on the restricting access to the at least a portion of the first storage device and providing access to the second storage device.

Example 21 may include the method of example 18, wherein restricting access to at least a portion of the first storage device includes denying, by the cache policy module, access to the first storage device.

Example 22 may include the method of any of examples 18 to 21, wherein the first storage device comprises a cache of the second storage device.

Various operations are described as multiple discrete operations in turn, in a manner that is most helpful in understanding the claimed subject matter. However, the order of description should not be construed as to imply that these operations are necessarily order dependent. Embodiments of the present disclosure may be implemented into a system using any suitable hardware and/or software to configure as desired.

Although certain embodiments have been illustrated and described herein for purposes of description, a wide variety of alternate and/or equivalent embodiments or implementations calculated to achieve the same purposes may be substituted for the embodiments shown and described without departing from the scope of the present disclosure. This application is intended to cover any adaptations or variations of the embodiments discussed herein. Therefore, it is manifestly intended that embodiments described herein be limited only by the claims and the equivalents thereof.

What is claimed is:

1. A computer system, comprising:
a first storage device having a first response time, and a second storage device coupled with the first storage device, and having a second response time that is higher than the first response time; and
a cache policy module to facilitate execution of input-output (I/O) requests to access the memory storage of the computer system, wherein the cache policy module is to restrict access to at least a portion of the first storage device and provide access to the second storage device, in response to an increase of temperature of the first storage device above a threshold.

2. The computer system of claim 1, wherein the first storage device comprises a cache of the second storage device.

3. The computer system of claim 2, wherein the second storage device comprises at least one of: a Serial Advanced Technology Attachment (SATA) hard disk drive (HDD), SATA solid state drive (SSD), Non-Volatile Memory express (NVMe) SSD, Embedded Multimedia Card (eMMC), or Universal Flash Storage (UFS).

4. The computer system of claim 2, wherein the first storage device comprises a solid state drive (SSD) or a hard disk drive (HDD).

5. The computer system of claim 1, further comprising one or more thermal sensors coupled with the first storage device, to provide readings of the temperature of the first storage device to the cache policy module.

6. The computer system of claim 1, wherein the cache policy module, in response to a decrease of the temperature of the first storage device to a value below the threshold, is to resume access to the first storage device.

7. The computer system of claim 1, further comprising a storage device controller coupled with the processor, wherein the storage device controller is to service the I/O requests according to instructions provided by the cache policy module.

8. The computer system of claim 7, wherein the cache policy module to restrict access to at least a portion of the first storage device includes to cause the storage device controller to deny access to the portion of the first storage device, and to cause data blocks stored in the portion of the first storage device to be marked as discarded data blocks.

9. The computer system of claim 8, wherein the I/O requests include a write request, wherein the cache policy module to control execution of input-output (I/O) requests includes to, in response to the write request, cause the storage device controller to:
determine that the write request is to be serviced by the first storage device;
determine that at least some of data blocks stored in the first storage device are marked as the discarded data blocks; and
write data associated with the write request to the second storage device.

10. The computer system of claim 8, wherein the I/O requests include a read request, wherein the cache policy module to control execution of input-output (I/O) requests includes to, in response to the read request, cause the storage device controller to:
determine that the read request is to be serviced by the first storage device;
determine that at least some of data blocks stored in the first storage device are marked as the discarded data blocks;
determine that at least one of the discarded data blocks is marked as a dirty block;
read data associated with the read request from the first storage device; and
update the data block marked as the dirty block on the second storage device, wherein a dirty block mark indicates that a data block has been updated on the first storage device, with respect to a copy of the data block stored on the second storage device.

11. The computer system of claim 1, wherein the cache policy module comprises one of: software module executable on a processor of a computer system, or firmware.

12. The computer system of claim 1, wherein the threshold is about 80 degrees Celsius, wherein the cache policy module to restrict access to at least a portion of the first storage device includes to deny access to the first storage device.

13. One or more non-transitory computer-readable media having instructions to control execution of input-output (I/O) requests to access a memory storage of a computer system, wherein the memory storage comprises first and second storage devices, wherein a response time of the first storage device is lower than a response time of the second storage device, wherein the instructions, in response to execution on a processor of the computer system, cause the processor to:
determine that a temperature of the first storage device is above a threshold; and
restrict access to at least a portion of the first storage device, and provide access to the second storage device.

14. The non-transitory computer-readable media of claim 13, wherein the instructions further cause the processor to deny access to the portion of the first storage device, and to mark as discarded data blocks stored in the portion of the first storage device.

15. The non-transitory computer-readable media of claim 13, wherein the I/O requests include a write request, wherein the instructions further cause the processor to:
determine that the write request is to be serviced by the first storage device;
determine that at least some of data blocks stored in the first storage device are marked as the discarded data blocks; and
write data associated with the write request to the second storage device

16. The non-transitory computer-readable media of claim 13, wherein the I/O requests include a read request, wherein the instructions further cause the processor to:
determine that the read request is to be serviced by the first storage device;
determine that at least some of data blocks stored in the first storage device are marked as the discarded data blocks;
determine that at least one of the discarded data blocks is marked as a dirty block;
read data associated with the read request from the first storage device; and
update the data block marked as the dirty block on the second storage device, wherein a dirty block mark indicates that a data block has been updated on the first storage device, with respect to a copy of the data block stored on the second storage device.

17. The computer system of claim 13, wherein the first storage device comprises a cache of the second storage device.

18. A method, comprising:
monitoring, by a cache policy module of a computer system, a temperature of a first storage device, wherein a memory storage of the computer system comprises the first storage device and a second storage device, wherein a response time of the first storage device is lower than a response time of the second storage device; and
restricting, by the cache policy module, access to at least a portion of the first storage device, and providing access to the second storage device, based at least in part on a result of the monitoring.

19. The method of claim 18, wherein monitoring the temperature of the first storage device includes determining, by the cache policy module, that the temperature of the first storage device exceeds a threshold.

20. The method of claim 18, further comprising:
updating, by the cache policy module, a cache policy of the computer system, based at least in part on the restricting access to the at least a portion of the first storage device and providing access to the second storage device.

21. The method of claim 18, wherein restricting access to at least a portion of the first storage device includes denying, by the cache policy module, access to the first storage device.

22. The method of claim 18, wherein the first storage device comprises a cache of the second storage device.
